(19) United States
(12) Patent Application Publication
(10) Pub. No.: US 2012/0113044 A1
(43) Pub. Date: May 10, 2012

(54) Multi-Sensor Device

(76) Inventors: Bradley Park Strazisar, Cary, NC (US); Julie Anne Morris, Raleigh, NC (US); James S. Rutledge, Durham, NC (US); Aaron Michael Stewart, Raleigh, NC (US); Harriss Christopher Neil Ganey, Virginia Beach, VA (US); Jay Wesley Johnson, Raleigh, NC (US)

(21) Appl. No.: 12/943,800

(22) Filed: Nov. 10, 2010

(51) Int. Cl. G06F 3/045; G01R 27/26; G06F 3/048; H01J 40/14

(52) U.S. Cl. 345/174; 250/221; 324/658; 715/764; 178/18.06

(57) ABSTRACT

A multi-sensor device includes an optical sensor portion and a capacitive sensor portion where the capacitive sensor portion borders the optical sensor portion. Various other devices, systems, methods, etc., are also disclosed.

### TECHNICAL FIELD

Subject matter disclosed herein generally relates to multi-sensor devices.

### BACKGROUND

Notebook computers, pads, media players, cell phones and other equipment typically include keys, buttons or touch screens that allow users to input information. For example, one popular smart phone includes a depressible button and a touch screen while another popular smart phone includes a depressible button and a keyboard. As for notebook computers, many include a touchpad with associated buttons. With the advent of “gestures” as a form of input, various conventional input devices have, in varying degrees, proven to be inadequate. As described herein, a multi-sensor device can be used to receive various types of user input.

### SUMMARY

A multi-sensor device includes an optical sensor portion and a capacitive sensor portion where the capacitive sensor portion borders the optical sensor portion. Various other devices, systems, methods, etc., are also disclosed.

### BRIEF DESCRIPTION OF THE DRAWINGS

Features and advantages of the described implementations can be more readily understood by reference to the following description taken in conjunction with examples of the accompanying drawings.

FIG. 1 is a series of diagrams of examples of devices;

FIG. 2 is a diagram of an example of a notebook computer that includes a multi-sensor device along with a block diagram of an example of a method;

FIG. 3 is a series of diagrams of examples of equipment that include a multi-sensor device along with block diagrams of examples of methods;

FIG. 4 is a diagram of an example of a phone that includes a multi-sensor device along with a block diagram of an example of a method;

FIG. 5 is a series of diagrams of examples of multi-sensor devices;

FIG. 6 is a diagram of an example of a device that includes a multi-sensor device along with diagrams of device circuitry;

FIG. 7 is a series of diagrams of examples of graphical user interfaces; and

FIG. 8 is a diagram of an example of a machine.

### DETAILED DESCRIPTION

The following description includes the best mode presently contemplated for practicing the described implementations. This description is not to be taken in a limiting sense, but rather is made merely for the purpose of describing the general principles of the implementations. The scope of the invention should be ascertained with reference to the issued claims.

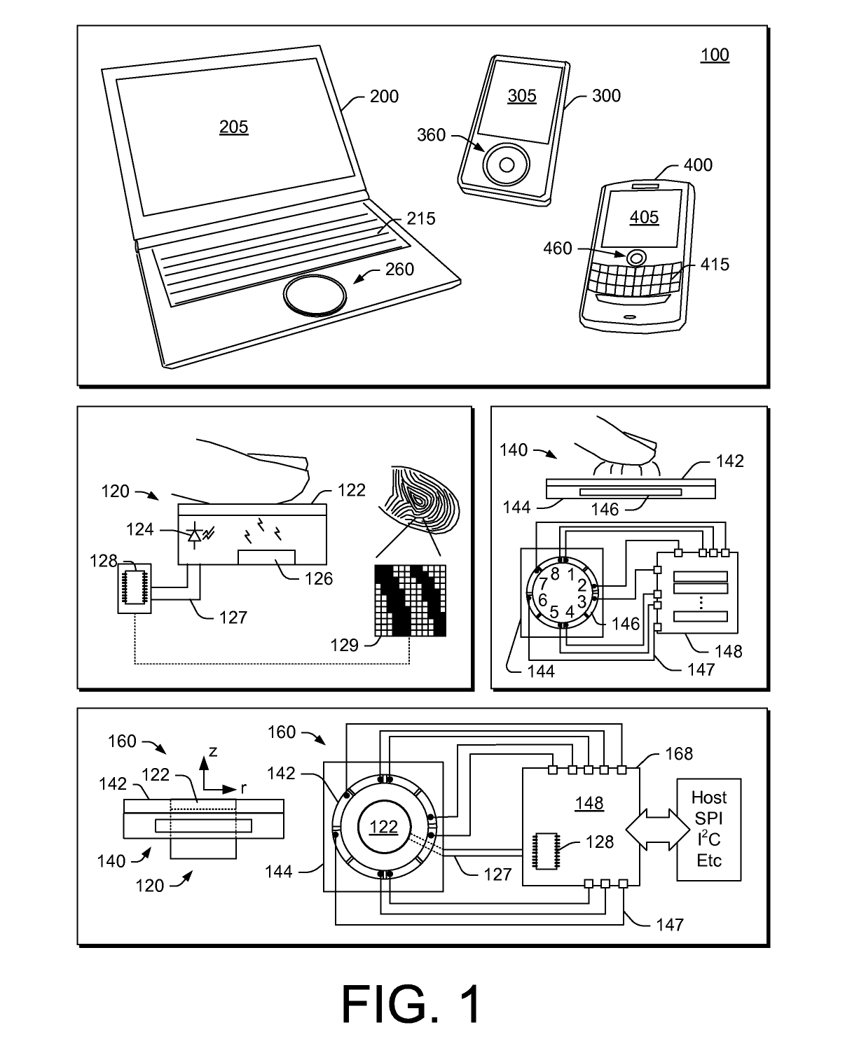

FIG. 1 shows various examples of equipment 100 that include a multi-sensor device. A notebook computer 200 includes a display 205, keys 215 and a multi-sensor device 260; a hand-holdable computer 300 includes a display 305 and a multi-sensor device 360; and a smart phone 400 includes a display 405, keys 415 and a multi-sensor device 460. As described herein, a multi-sensor device 160 includes an optical sensor 120 and a capacitive sensor 140, which are at times referred to as an optical sensor portion and a capacitive sensor portion, respectively.

In various examples, a multi-sensor device is configured such that a capacitive sensor borders, at least partially, an optical sensor. For example, a multi-sensor can include a capacitive ring-shaped input sensor that surrounds an optical sensor by 360 degrees where the optical sensor functions as a small touchpad (e.g., enabling simple up, down, left, and right gestures, taps, and clicks) while the ring-shaped outer sensor enables additional use cases (e.g., left and right click, rotate, zoom, traversing menus, flicks, etc, with various movements including swiping CW or CCW, moving multiple fingers in the same or opposite directions, etc.). In such an example, the multi-sensor device can allow for gestures that are more intuitive and easier to discover than with conventional input devices (e.g., optionally allowing for new gestures to be added).

In various examples, control circuitry can implement various types of logic, which may, for example, determine when contact with a capacitive sensor takes precedence even though some contact occurs with an optical sensor (e.g., and vice versa). Precedence may optionally be determined by which sensor experiences a majority of contact or other technique or rule (e.g., a precedence rule).

FIG. 1 shows an example of an optical sensor 120, an example of a capacitive sensor 140 and an example of a multi-sensor device 160. The optical sensor 120 may be configured as a so-called “optical trackpad”. An optical trackpad is generally a sensor shaped as a “pad” configured to track an object using optical components. As described herein, tracking can include, for example, detecting presence or an object or objects, absence of an object or objects or motion of an object or objects.

In the example of FIG. 1, the optical sensor 120 includes a surface 122, an emitter 124, a detector 126, connectors 127 and circuitry 128, which may be configured to output sensed information in the form of a digital array 129. For example, an object may be a finger or other object with surface indicia (e.g., consider fingerprint ridges, striations, or other indicia). When such an object contacts or comes into close proximity to the surface 122, surface indicia of the object are illuminated by radiation emitted by the emitter 124 (e.g., an emitting diode). Radiation reflected by the object (e.g., optionally due to impedance/index of refraction changes of a boundary of the surface 122) is detected by the detector 126. The detector 126 may be a CCD or other type of detector.

In the example of FIG. 1, the capacitive sensor 140 includes a surface 142 (e.g., a cover of plastic or other material), a board 144, a ring-shaped electrode array 146, connectors 147 and circuitry 148. While a single board 144 is shown to achieve higher resolution more than one board may be included in a multi-sensor device. For the particular sensor 140, capacitance changes are measured from each electrode of the array 146 where the board 144 operates as a plate of a virtual capacitor and where a user's finger operates as another plate of the virtual capacitor (e.g., which is grounded with respect to the sensor input). In operation, the circuitry 148 outputs an excitation signal to charge the board 144 plate and, when the user comes close to the sensor 140, the virtual capacitor is formed (i.e., where the user acts as the second capacitor plate). The circuitry 148 may be configured for communication via a SPI, I²O or other interface.

As shown in the example of FIG. 1, the capacitive sensor 140 includes 8 electrodes. As described herein, a capacitive sensor may include any of a variety of number of electrodes and arrangement of electrodes. Circuitry may be configured to sense multiple “touches” (e.g., signals from multiple electrodes). Circuitry may relate one or more electrodes to various functions and optionally gestures that may rely on sensing by multiple electrodes and optionally time dependency (e.g., delays, velocity, acceleration, order, etc.).

In the example of FIG. 1, the multi-sensor device 160 includes an optical sensor 120 and a capacitive sensor 140 where the capacitive sensor 140 surrounds the optical sensor 120. In other words, according to the example of FIG. 1, a capacitive sensor portion of a multi-sensor device may surround an optical sensor portion of the multi-sensor device. The optical sensor 120 may be thicker (e.g., along a z-coordinate) as capacitive sensors can be manufactured with minimal thickness (e.g., as thin as a PCB or flex circuit may allow). As shown in FIG. 1, the connector 127 connects various components of the optical sensor 120 to circuitry 168, which may include circuitry such as the circuitry 128, while the connectors 147 connect the electrode array 142 to the circuitry 168, which may include circuitry such as the circuitry 148. Accordingly, as described herein, circuitry may include (e.g., on a single chip or board) circuitry configured for both optical input and capacitive input. While the optical sensor 120 is shown with a circular configuration, an optical sensor of a multi-sensor device may have a different configuration (e.g., rectangular, other polygon, elliptical, etc.). Similarly, while the capacitive sensor 140 is shown with a circular configuration, a capacitive sensor of a multi-sensor device may have a different configuration (e.g., rectangular, other polygon, elliptical, etc.). With respect to height, a capacitive sensor may have a height that differs from that of an optical sensor. For example, consider a raised capacitive ring that surrounds an optical sensor. In such an arrangement, the ring may be raised by a few millimeters to provide for tactile feedback to a user (e.g., to help a user selectively avoid input to the optical sensor when providing input to the ring, etc.). Further, the outer surface of a capacitive sensor may differ from that of an outer surface of an optical sensor to provide tactile feedback (e.g., consider a capacitive ring surface notched at arc intervals versus a smooth surface of an optical sensor).

As described herein, a sensor may operate according to one or more algorithms that can output information that corresponds to planar coordinates (e.g., x, y). For example, a sensor or sensor circuitry may output one or more x, y, Δx, Δy, etc., values. A sensor or sensor circuitry may include a sampling rate such that, for example, values for x, y, Δx, Δy, etc., may be determined with respect to time. A sensor may optionally provide for proximity (e.g., in a third dimension z). For example, a capacitive sensor may be programmed to output information based on proximity of a finger to an electrode or electrodes of an array (e.g., based on distance separating plates of a virtual capacitor).

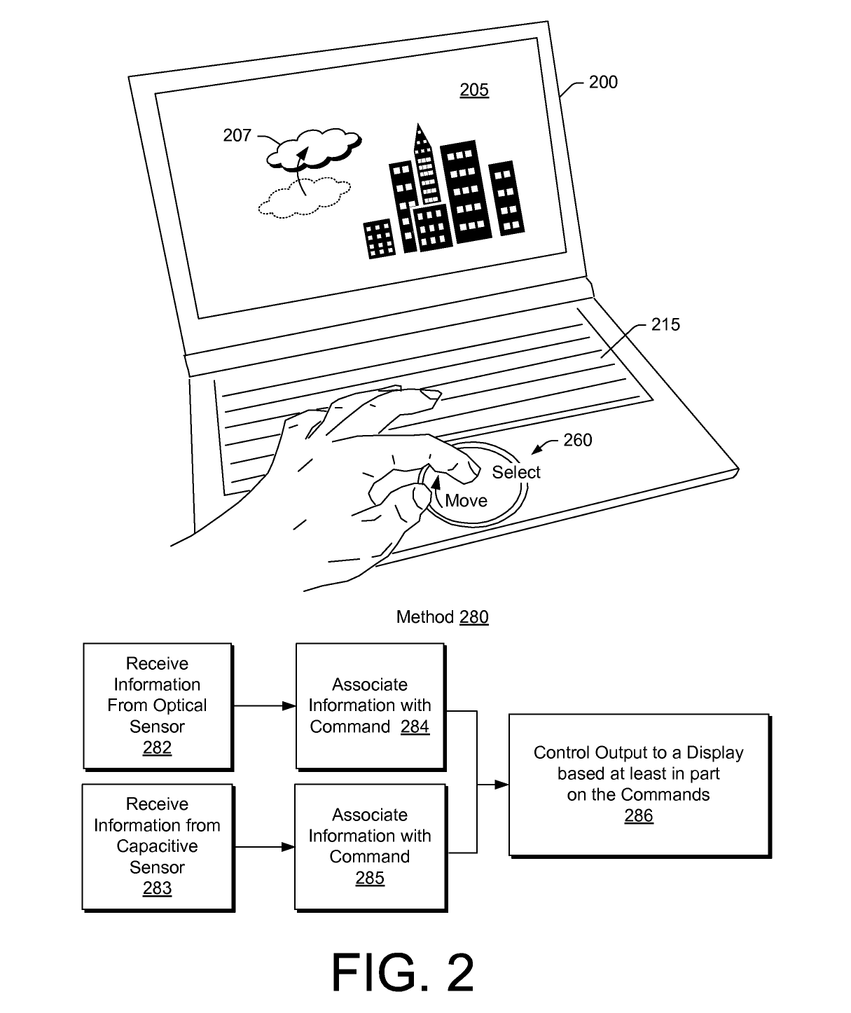

FIG. 2 shows the notebook computer 200 with various graphics rendered to the display 205 along with an example of a method 280 for using the multi-sensor device 260. The method 280 includes two reception blocks 282 and 283 for receiving information from an optical sensor and for receiving information from a capacitive sensor. As shown, association blocks 284 and 285 are provided for associating received information with commands. The method 280 further includes a control block 286 for controlling output to a display based at least in part on the commands. For example, consider a method where a user uses one finger to maneuver a cursor and select an object rendered to a display (e.g., the displayed cloud object 207) via the optical sensor portion of the multi-sensor device 260 and another finger to move the selected object via the capacitive sensor portion of the multi-sensor device 260. While “select” and “move” commands are illustrated, any of a variety of commands may be associated with received information from a multi-sensor device. For example, an alteration command (e.g., delete object or highlight object) may be input by a double tap to the capacitive sensor portion of a multi-sensor device or consider an alteration command that zooms an object (e.g., enlarge or shrink) by moving a finger towards 12 o'clock or 6 o'clock on a ring-shaped capacitive sensor portion of a multi-sensor device. Various action commands may also be possible (e.g., save, open, close, etc.) and operate in conjunction with one or more graphical user interfaces (GUIs). Further, as mentioned, a multi-sensor device may be configured for input via gestures, which may rely on multiple fingers, multiple touches by a single finger, etc.

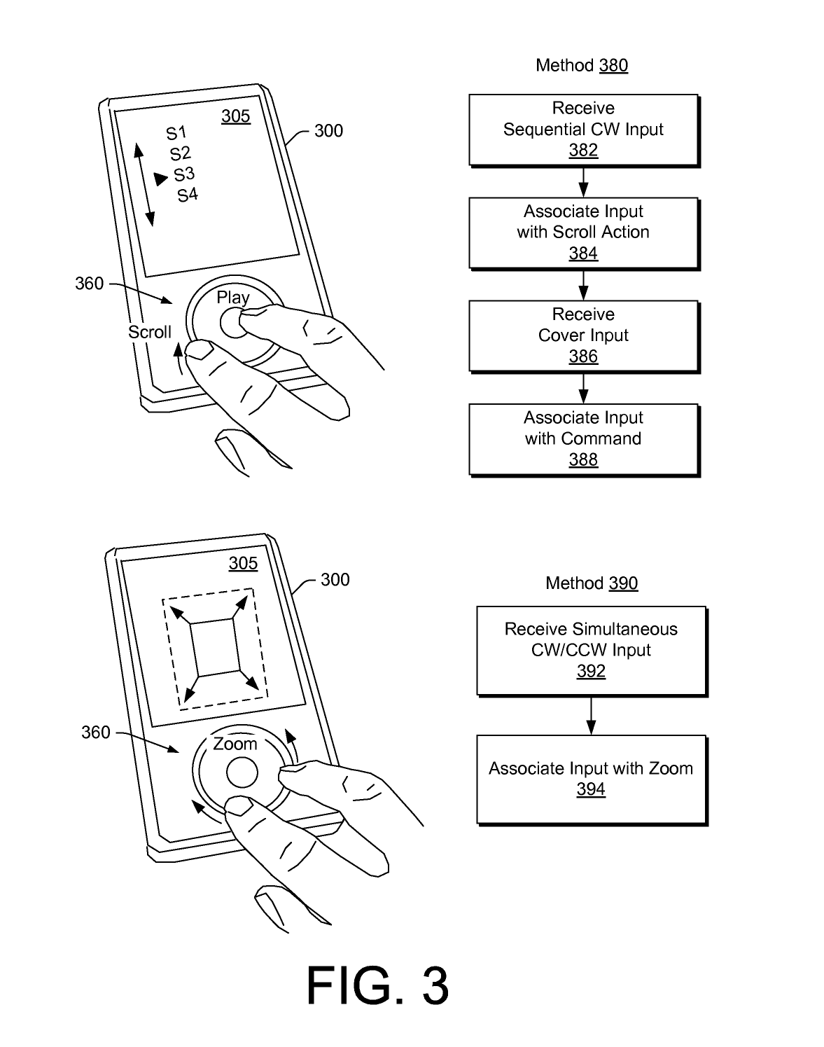

FIG. 3 shows the hand-holdable computer 300 as including the display 305 and multi-sensor device 360 along with examples of two methods 380 and 390. The method 380 includes a reception block 382 for receiving sequential clockwise (CW) input via a ring-shaped capacitive sensor portion of a multi-sensor device. An association block 384 provides for associating the input with a scroll action. Another reception block 386 provides for receiving cover input via an optical sensor portion of a multi-sensor device, which, per an association block 388, is associated with a command. For example, as shown in FIG. 3, a media list is rendered to the display 305 where a user may scroll a cursor by moving a finger along the capacitive sensor portion of the multi-sensor device 360. Once the cursor is aligned with a particular member of the media list, the user may cover or touch the optical sensor portion of the multi-sensor device 360 to initiate a play command to play the media.

The method 390 includes a reception block 392 for simultaneously receiving clockwise (CW) and counter-clockwise (CCW) input and an association block 394 for associating the input with a zoom command. For example, as shown in FIG. 3, an image is rendered to the display 305, which may be enlarged by moving one finger in a clockwise direction and another finger in a counter-clockwise direction along the capacitive sensor portion of the multi-sensor device 360.

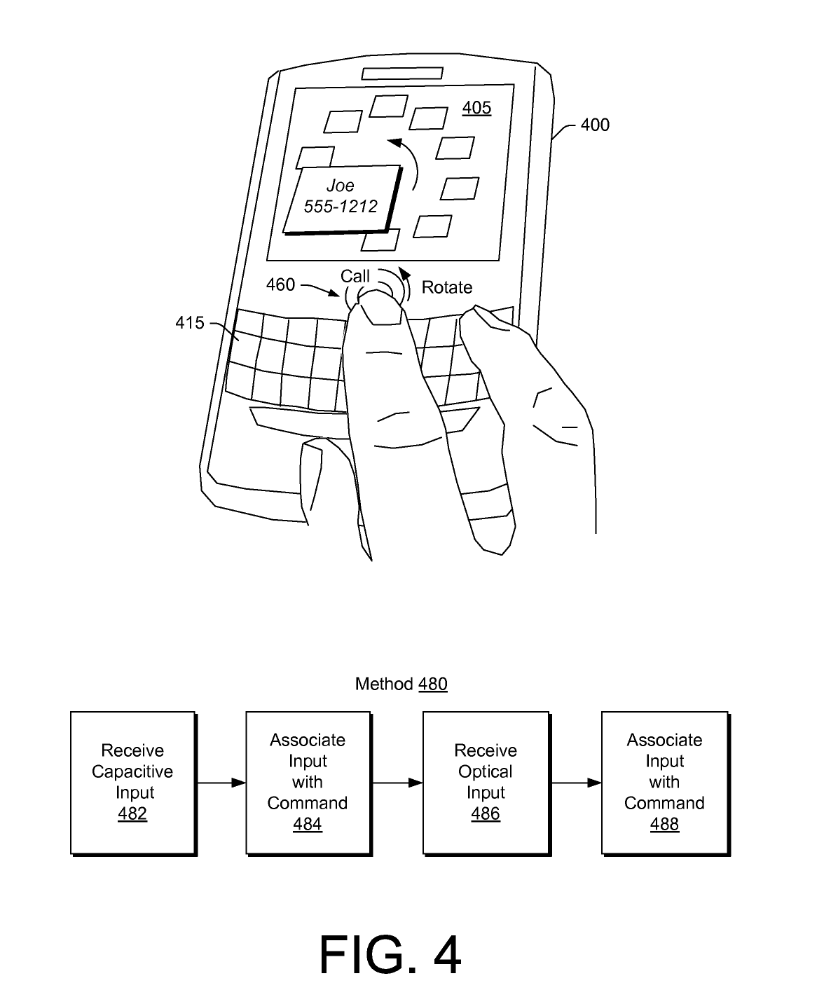

FIG. 4 shows the smart phone 400 as including the display 405, keys 415 and the multi-sensor device 460 along with an example of a method 480. The method 480 includes a reception block 482 for receiving input via a capacitive sensor portion of a multi-sensor device. An association block 484 provides for associating the input with a command. Another reception block 486 provides for receiving input via an optical sensor portion of a multi-sensor device, which, per an association block 488, is associated with a command. For example, as shown in FIG. 4, contact information is rendered to the display 405 where a user may navigate the information by moving a finger along the capacitive sensor portion of the multi-sensor device 460. Once the desired contact is found, the user may cover or touch the optical sensor portion of the multi-sensor device 460 to initiate a communication based at least in part on information associated with the contact. For example, the phone 400 may include a rolodex type of function that can be navigated using one sensor and activated using another sensor.

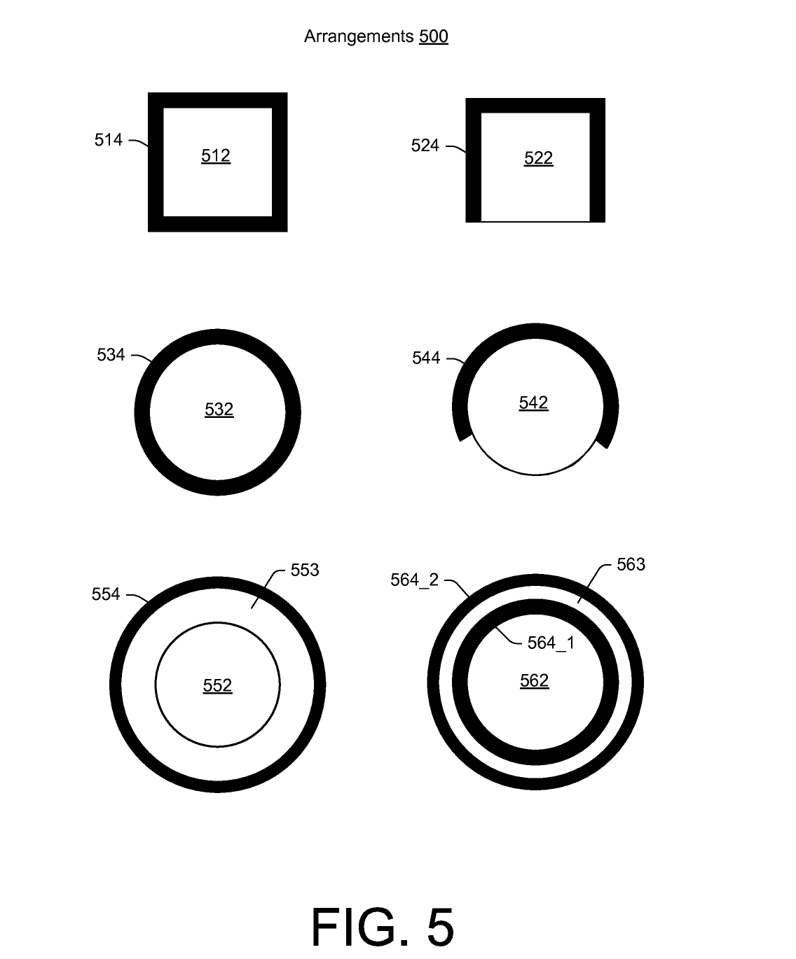

FIG. 5 shows various examples of arrangements for a multi-sensor device 500. As shown, an arrangement can includes a square optical sensor portion 512 and a square, bordering capacitive sensor portion 514; a square optical sensor portion 522 and a U-shaped capacitive sensor portion 524; a circular optical sensor portion 532 and a circular capacitive sensor portion 534; a circular optical sensor portion 542 and a C-shaped, bordering capacitive sensor portion 544; an optical sensor portion 552, a gap or spacer 553 and a capacitive sensor portion 554; or an optical sensor portion 562, an inner capacitive sensor portion 564_1 and an outer capacitive sensor portion 564_2, where the capacitive sensor portions 564_1 and 564_2 may be separated by a gap or spacer 563. Other examples of arrangements are also possible (e.g., triangular sensor portions, rectangular portion inside a circular portion, etc.).

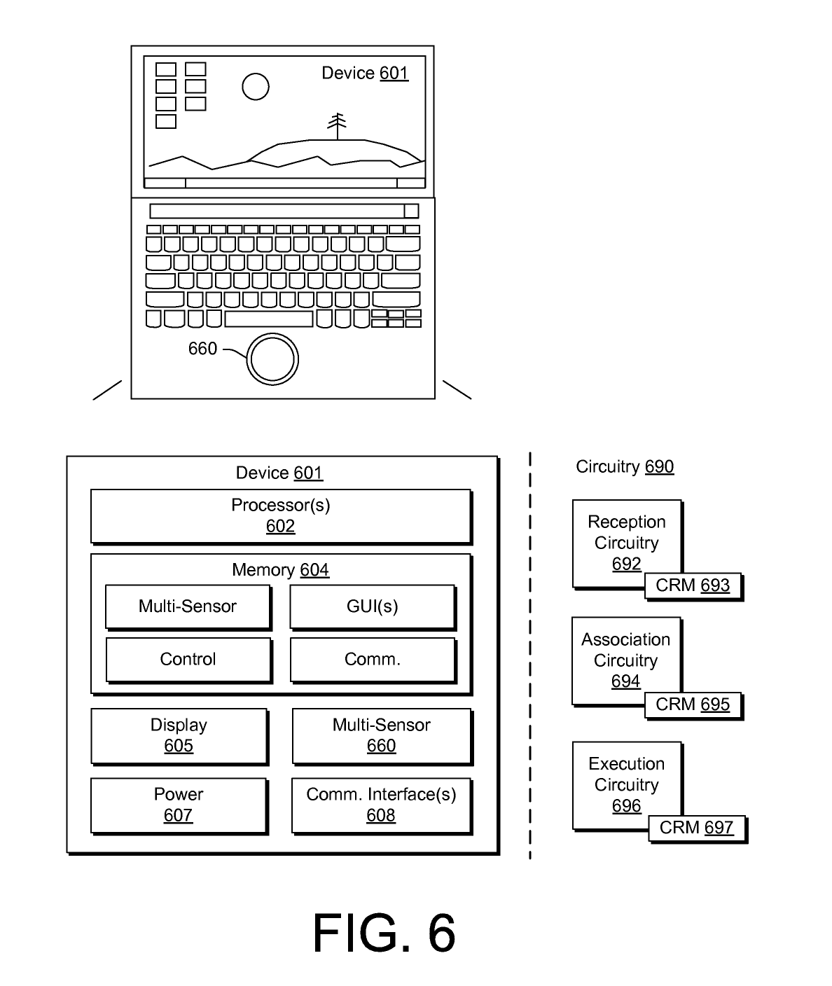

FIG. 6 shows an example of a device 601 as well as some examples of circuitry 690 that may be included in the device 601. In the example of FIG. 6, the device 601 includes one or more processors 602 (e.g., cores), memory 604, a display 605, a multi-sensor device 660, a power supply 607 and one or more communication interfaces 608. As described herein, a communication interface may be a wired or a wireless interface. In the example of FIG. 6, the memory 604 can include one or more modules such as, for example, a multi-sensor module, a control module, a GUI module and a communication module. Such modules may be provided in the form of instructions, for example, directly or indirectly executable by the one or more processors 602.

The device 601 may include the circuitry 690. In the example of FIG. 6, the circuitry 690 includes reception circuitry 692, association circuitry 694 and execution circuitry 696. Such circuitry may optionally rely on one or more computer-readable media that includes computer-executable instructions. For example, the reception circuitry 692 may rely on CRM 693, the association circuitry 694 may rely on CRM 695 and the execution circuitry 696 may rely on CRM 697. While shown as separate blocks, one or more of the CRM 693, CRM 695 and CRM 697 may be provided as a package (e.g., optionally in the form of a single computer-readable storage medium). As described herein, a computer-readable medium may be a storage device (e.g., a memory card, a storage disk, etc.) and referred to as a computer-readable storage medium.

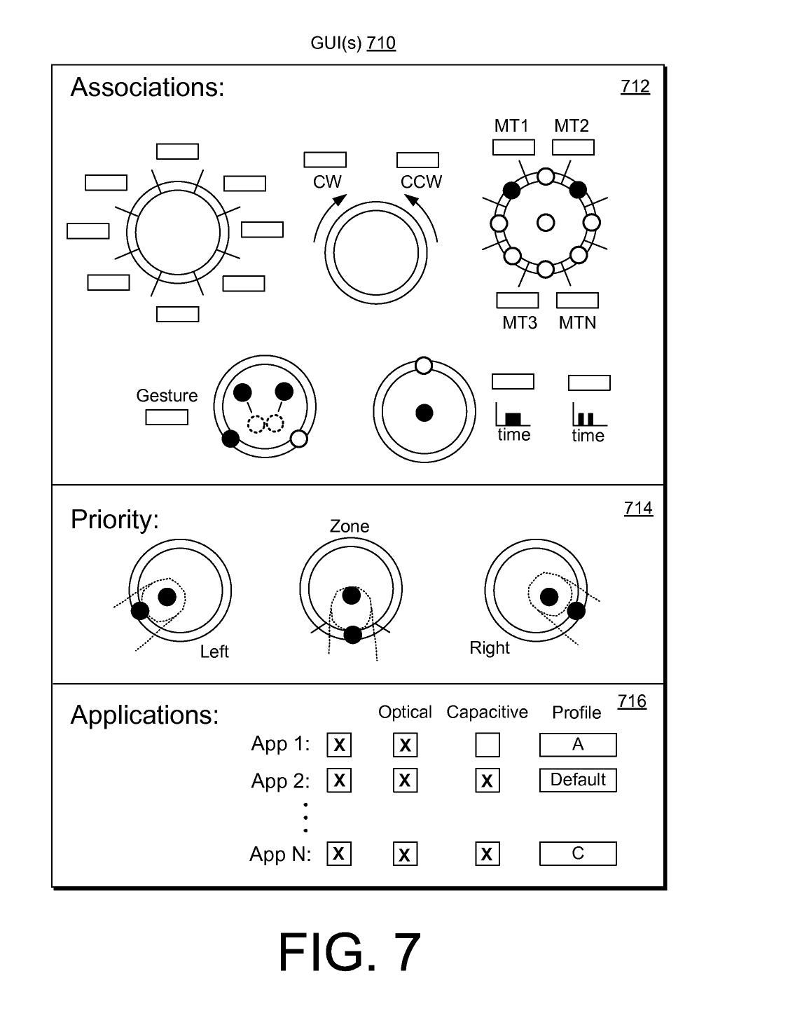

FIG. 7 shows various example graphical user interfaces (GUIs) 710. As described herein, a device (e.g., the device 601 of FIG. 6) may include circuitry configured for presentation of one or more GUIs. In the example of FIG. 7, a GUI may include association GUI controls 712, priority GUI controls 714, application GUI controls 716 or one or more additional or other GUI controls.

As to the association GUI controls 712, default associations may be set. However, options may exist that allow for association of input with particular commands. In the examples of FIG. 7, the association GUI controls 712 include a capacitive sensor portion association control where a user may select a segment or segments and associate activation of the segment or segments with a command; a capacitive sensor portion association control where a user may associate clockwise motion with a command and counter-clockwise motion with a command; a multi-sensor association control where a user may associate each of various types of activation (e.g., multi-“touch”, which may include multi-sensor activation) with a respective command; a multi-sensor association control where a user may associate a gesture with a command; and a single or multi-sensor control where a user may associate duration of activation, sequence of activation, etc., with respective commands. As shown, an association GUI control may allow for setting “hold”, “double-click” or other types of activation with commands.

As to the examples of priority GUI controls 714, as described herein, such controls may be used to determine priority of activation when multiple sensors are activated. For example, a left finger (e.g., left index finger) may activate a capacitive sensor portion and an optical sensor portion of a multi-sensor device. In such an example, a user may desire to have activation of the capacitive sensor portion primary to activation of the optical sensor portion. Accordingly, control circuitry may register activation of both sensor portions by a finger in a substantially simultaneous manner and repress any activation signal stemming from the finger with respect to the optical sensor portion. Another GUI control for a right finger (e.g., right index finger) may allow a user to set optical sensor input as having priority when a finger activates (e.g., substantially simultaneously) a capacitive sensor portion and a proximate optical sensor portion of a multi-sensor device. Yet another GUI control may allow for setting a zone along a capacitive sensor portion. For example, such a zone may be a “dead” zone where proximity to or contact with the capacitive sensor portion does not alter input received via the optical sensor portion of a multi-sensor device.

As to the applications GUI controls 716, an option may exist to link a multi-sensor profile to one or more applications. Further, options may exist to activate the optical sensor portion, the capacitive sensor portion or both optical sensor and capacitive sensor portions of a multi-sensor device. As to profiles, profile information may exist in the form of an accessible stored file (e.g., accessible locally or remotely). A profile may be available specifically for an application, as an equipment default, a user created settings, etc.

As described herein, a multi-sensor device can include an optical sensor portion and a capacitive sensor portion where the capacitive sensor portion borders the optical sensor portion. In such a device, the optical sensor portion may include an emitter to emit radiation and a detector to detect emitted radiation reflected by an object to thereby track movement of the object.

As described herein, a multi-sensor device may have associated circuitry (e.g., of the device or a host) that includes control circuitry configured to control output to a display based on input received from an optical sensor portion, based on input received from an capacitive sensor portion or based on input received from an optical sensor portion and a capacitive sensor portion. In a particular example, control circuitry is configured to control position of an image on a display based on input from an optical sensor portion of a multi-sensor device. Such an image may be a graphic image, a text image, or a photographic image. As described herein, an image may be a cursor image. In various examples, control circuitry may be configured to control size of an image on a display based on input from a capacitive sensor portion of a multi-sensor device. As described herein, a capacitive sensor portion may include a multi-touch capacitive sensor, for example, where control circuitry is configured to control output to a display based at least in part on multi-touch input from the capacitive sensor portion.

As described herein, control circuitry may be configured to prioritize input from an optical sensor portion over input from a capacitive sensor portion or to prioritize input from a capacitive sensor portion over input from an optical sensor portion.

As described herein, a method can include receiving input from an optical sensor, associating the input from the optical sensor with a first command, receiving input from a capacitive sensor, associating the input from the capacitive sensor with a second command and controlling output to a display based on the first command and the second command. In such a method, the first command may be, for example, a selection command to select a displayed object and the second command may be an alteration command to alter display of an object. In another example, commands may include a selection command to select an object and an action command to perform an action with respect to the selected object. In various examples, a method may include receiving input from the capacitive sensor comprises receiving multi-touch input.

As described herein, one or more computer-readable media can include computer-executable instructions to instruct a computer (e.g., a notebook, a pad, a cell phone, a camera, etc.) to associate input from an optical sensor and input from a capacitive sensor with a first action and a second action and execute the second action based at least in part on the first action. In such an example, the first action may be a selection action to select an object and the second action may be an action that acts on the selected object. As described herein, one or more computer-readable media can include computer-executable instructions to instruct a computer to display a graphical user interface with selectable controls to associate input from an optical sensor with an action and computer-executable instructions to instruct a computer to display a graphical user interface with selectable controls to associate input from a capacitive sensor with an action. As mentioned, other possibilities exist, for example, consider the various GUI controls 710 of FIG. 7, which may be provided in the form of one or more computer-readable media and executed by computer (e.g., a notebook, a pad, a cell phone, a camera, etc.).

The term “circuit” or “circuitry” is used in the summary, description, and/or claims. As is well known in the art, the term “circuitry” includes all levels of available integration, e.g., from discrete logic circuits to the highest level of circuit integration such as VLSI, and includes programmable logic components programmed to perform the functions of an embodiment as well as general-purpose or special-purpose processors programmed with instructions to perform those functions. Such circuitry may optionally rely on one or more computer-readable media that includes computer-executable instructions. As described herein, a computer-readable medium may be a storage device (e.g., a memory card, a storage disk, etc.) and referred to as a computer-readable storage medium.

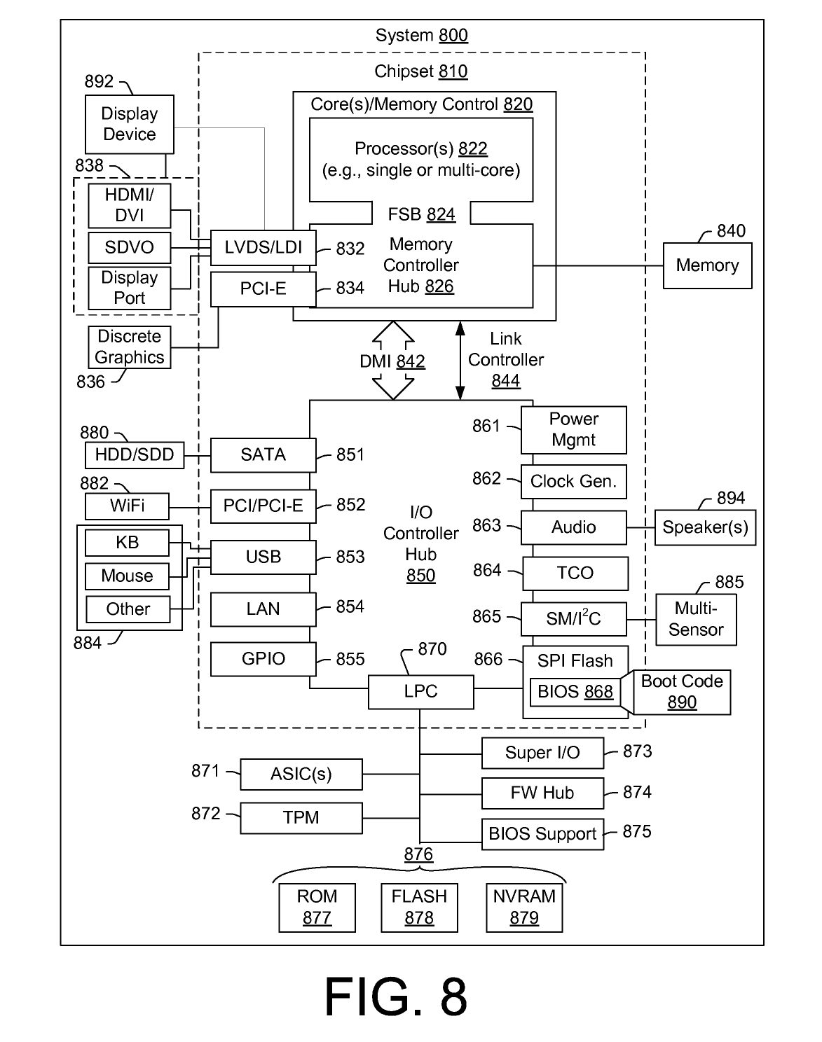

While various examples of circuits or circuitry have been discussed, FIG. 8 depicts a block diagram of an illustrative computer system 800. The system 800 may be a desktop computer system, such as one of the ThinkCentre® or ThinkPad® series of personal computers sold by Lenovo (US) Inc. of Morrisville, N.C., or a workstation computer, such as the ThinkStation®, which are sold by Lenovo (US) Inc. of Morrisville, N.C.; however, as apparent from the description herein, a satellite, a base, a server or other machine may include other features or only some of the features of the system 800. As described herein, a device such as the device 601 may include at least some of the features of the system 800.

As shown in FIG. 8, the system 800 includes a so-called chipset 810. A chipset refers to a group of integrated circuits, or chips, that are designed to work together. Chipsets are usually marketed as a single product (e.g., consider chipsets marketed under the brands INTEL®, AMD®, etc.).

In the example of FIG. 8, the chipset 810 has a particular architecture, which may vary to some extent depending on brand or manufacturer. The architecture of the chipset 810 includes a core and memory control group 820 and an I/O controller hub 850 that exchange information (e.g., data, signals, commands, etc.) via, for example, a direct management interface or direct media interface (DMI) 842 or a link controller 844. In the example of FIG. 8, the DMI 842 is a chip-to-chip interface (sometimes referred to as being a link between a “northbridge” and a “southbridge”).

The core and memory control group 820 include one or more processors 822 (e.g., single core or multi-core) and a memory controller hub 826 that exchange information via a front side bus (FSB) 824. As described herein, various components of the core and memory control group 820 may be integrated onto a single processor die, for example, to make a chip that supplants the conventional “northbridge” style architecture.

The memory controller hub 826 interfaces with memory 840. For example, the memory controller hub 826 may provide support for DDR SDRAM memory (e.g., DDR, DDR2, DDR3, etc.). In general, the memory 840 is a type of random-access memory (RAM). It is often referred to as “system memory”.

The memory controller hub 826 further includes a low-voltage differential signaling interface (LVDS) 832. The LVDS 832 may be a so-called LVDS Display Interface (LDI) for support of a display device 892 (e.g., a CRT, a flat panel, a projector, etc.). A block 838 includes some examples of technologies that may be supported via the LVDS interface 832 (e.g., serial digital video, HDMI/DVI, display port). The memory controller hub 826 also includes one or more PCI-express interfaces (PCI-E) 834, for example, for support of discrete graphics 836. Discrete graphics using a PCI-E interface has become an alternative approach to an accelerated graphics port (AGP). For example, the memory controller hub 826 may include a 16-lane (x16) PCI-E port for an external PCI-E-based graphics card. A system may include AGP or PCI-E for support of graphics.

The I/O hub controller 850 includes a variety of interfaces. The example of FIG. 8 includes a SATA interface 851, one or more PCI-E interfaces 852 (optionally one or more legacy PCI interfaces), one or more USB interfaces 853, a LAN interface 854 (more generally a network interface), a general purpose I/O interface (GPIO) 855, a low-pin count (LPC) interface 870, a power management interface 861, a clock generator interface 862, an audio interface 863 (e.g., for speakers 894), a total cost of operation (TCO) interface 864, a system management bus interface (e.g., a multi-master serial computer bus interface) 865, and a serial peripheral flash memory/controller interface (SPI Flash) 866, which, in the example of FIG. 8, includes BIOS 868 and boot code 890. With respect to network connections, the I/O hub controller 850 may include integrated gigabit Ethernet controller lines multiplexed with a PCI-E interface port. Other network features may operate independent of a PCI-E interface.

The interfaces of the I/O hub controller 850 provide for communication with various devices, networks, etc. For example, the SATA interface 851 provides for reading, writing or reading and writing information on one or more drives 880 such as HDDs, SDDs or a combination thereof. The I/O hub controller 850 may also include an advanced host controller interface (AHCI) to support one or more drives 880. The PCI-E interface 852 allows for wireless connections 882 to devices, networks, etc. The USB interface 853 provides for input devices 884 such as keyboards (KB), mice and various other devices (e.g., cameras, phones, storage, media players, etc.). The bus 865 may be configured as, for example, an I²C bus and suitable for receipt of information from a multi-sensor 885 (see, e.g., the multi-sensor 160 of FIG. 1).

In the example of FIG. 8, the LPC interface 870 provides for use of one or more ASICs 871, a trusted platform module (TPM) 872, a super I/O 873, a firmware hub 874, BIOS support 875 as well as various types of memory 876 such as ROM 877, Flash 878, and non-volatile RAM (NVRAM) 879. With respect to the TPM 872, this module may be in the form of a chip that can be used to authenticate software and hardware devices. For example, a TPM may be capable of performing platform authentication and may be used to verify that a system seeking access is the expected system.

The system 800, upon power on, may be configured to execute boot code 890 for the BIOS 868, as stored within the SPI Flash 866, and thereafter processes data under the control of one or more operating systems and application software (e.g., stored in system memory 840). An operating system may be stored in any of a variety of locations and accessed, for example, according to instructions of the BIOS 868. Again, as described herein, a satellite, a base, a server or other machine may include fewer or more features than shown in the system 800 of FIG. 8.

### CONCLUSION

Although examples of methods, devices, systems, etc., have been described in language specific to structural features and/or methodological acts, it is to be understood that the subject matter defined in the appended claims is not necessarily limited to the specific features or acts described. Rather, the specific features and acts are disclosed as examples of forms of implementing the claimed methods, devices, systems, etc.

What is claimed is:

1. An apparatus comprising:
an optical sensor portion; and
a capacitive sensor portion wherein the capacitive sensor portion borders the optical sensor portion.

2. The apparatus of claim 1 wherein the optical sensor portion comprises an emitter to emit radiation and a detector to detect emitted radiation reflected by an object to thereby track movement of the object.

3. The apparatus of claim 1 further comprising control circuitry configured to control output to a display based on input received from the optical sensor portion, based on input received from the capacitive sensor portion or based on input received from the optical sensor portion and the capacitive sensor portion.

4. The apparatus of claim 3 wherein the control circuitry is configured to control position of an image on a display based on input from the optical sensor portion.

5. The apparatus of claim 4 wherein the image comprises an image selected from a group consisting of a graphic image, a text image, and a photographic image.

6. The apparatus of claim 5 wherein the graphic image comprises a cursor image.

7. The apparatus of claim 3 wherein the control circuitry is configured to control size of an image on a display based on input from the capacitive sensor portion.

8. The apparatus of claim 1 wherein the capacitive sensor portion comprises a multi-touch capacitive sensor.

9. The apparatus of claim 8 further comprising control circuitry configured to control output to a display based at least in part on multi-touch input from the capacitive sensor portion.

10. The apparatus of claim 1 further comprising control circuitry configured to prioritize input from the optical sensor portion over input from the capacitive sensor portion or to prioritize input from the capacitive sensor portion over input from the optical sensor portion.

11. A method comprising:
receiving input from an optical sensor;
associating the input from the optical sensor with a first command;
receiving input from a capacitive sensor;
associating the input from the capacitive sensor with a second command; and
controlling output to a display based on the first command and the second command.

12. The method of claim 11 wherein the first command comprises a selection command to select a displayed object.

13. The method of claim 11 wherein the second command comprises an alteration command to alter display of an object.

14. The method of claim 11 wherein the first command comprises a selection command to select a displayed object and wherein the second command comprises an alteration command to alter display of the selected object.

15. The method of claim 11 wherein the commands comprise a selection command to select an object and an action command to perform an action with respect to the selected object.

16. The method of claim 11 wherein the receiving input from the capacitive sensor comprises receiving multi-touch input.

17. One or more computer-readable media comprising computer-executable instructions to instruct a computer to:
associate input from an optical sensor and input from a capacitive sensor with a first action and a second action; and
execute the second action based at least in part on the first action.

18. The one or more computer-readable media of claim 17 wherein the first action comprises a selection action to select an object and wherein the second action comprises an action that acts on the selected object.

19. The one or more computer-readable media of claim 17 further comprising computer-executable instructions to instruct a computer to display a graphical user interface with selectable controls to associate input from an optical sensor with an action.

20. The one or more computer-readable media of claim 17 further comprising computer-executable instructions to instruct a computer to display a graphical user interface with selectable controls to associate input from a capacitive sensor with an action.
